(19) United States
(12) Patent Application Publication
(10) Pub. No.: US 2012/0250228 A1
(43) Pub. Date: Oct. 4, 2012

(54) PORTABLE ELECTRONIC APPARATUS

(76) Inventor: Kuan-Hsueh Tseng, Hsinchu (TW)

(21) Appl. No.: 13/115,998

(22) Filed: May 26, 2011

(30) Foreign Application Priority Data
Mar. 28, 2011 (TW) 100110576

(51) Int. Cl. H05K 5/04

(52) U.S. Cl. 361/679.01

(57) ABSTRACT

A portable electronic apparatus includes a host, a pivotal connection device, a display, and an antenna. The host includes a base casing and an electronic device. The base casing has a side portion. The display is pivotally connected to the side portion through the pivotal connection device. The base casing thereon defines an antenna radiation reference surface. The side portion has a first accommodating space and a second accommodating space adjacent to each other. The projections of the first and second accommodating spaces on the antenna radiation reference are non-overlapped. The electronic device is disposed in the first accommodating space, the antenna in the second accommodating space. Thereby, the antenna is not influenced by the material of the casing of the display and still can perform wireless communication, which solves the plight of having to cut a metal upper casing in the prior art where an antenna is disposed.

### BACKGROUND OF THE INVENTION

1. Field of the Invention

The invention relates to a portable electronic apparatus, and especially relates to a portable electronic apparatus with an antenna disposed in a base casing thereof.

2. Description of the Prior Art

As electronic manufacturing technology develops, various portable electronic apparatuses have been widely used. The most common one is notebook. The current notebook usually has wireless communication function. The antenna of the notebook is usually disposed on an outer portion of the whole structure of the notebook in operation, such as the upper portion of the screen of the notebook. Because of antenna properties, it is improper in principle to dispose any metal parts irrelative to the operation of the antenna at the place where the antenna is disposed. Therefore, the top portion of the upper casing of the notebook is usually made of nonmetal material; that is, if the upper casing is made of metal, the top portion thereof requires a broken hole for the antenna to function normally.

As electronic apparatuses are designed toward the lightness and thinness, metal has been used widely in structure designs due to its higher strength. Besides, the textural feeling and appearance of the surface of a part formed of metal are still popular to people, so in industry design, there are many products with casing totally made of metal. If the upper casing of a notebook is totally made of metal or at least the back plate (i.e. the exposed plate part of the notebook having been folded) of the upper casing thereof is totally made of metal, it is improper to dispose the antenna in the upper casing. In this case, if the antenna is disposed on the outside of the upper casing, the appearance of the upper casing will be spoiled easily. The design for the metal casing and the disposition of the antenna are therefore mired in difficulties.

### SUMMARY OF THE INVENTION

To the problem in the prior art, an objective of the invention is to provide a portable electronic apparatus. An antenna of the portable electronic apparatus is disposed in a base casing of the portable electronic apparatus, so as to preserve the design of whole metal plate for an upper casing pivotally connected to the base casing, which satisfies the design requirement for the appearance of the upper casing.

The portable electronic apparatus according to the invention includes a host, a pivotal connection device, a display, and an antenna. The host includes a base casing and an electronic device. The base casing has a side portion. The base casing thereon defines an antenna radiation reference surface. The side portion includes a first accommodating space and a second accommodating space. The first accommodating space is adjacent to the second accommodating space. Projections of the first accommodating space and the second accommodating space on the antenna radiation reference surface are non-overlapped. The electronic device is disposed in the first accommodating space. The display includes an upper casing. The upper casing is pivotally connected to the side portion by the pivotal connection device. The antenna is disposed in the second accommodating space.

Therefore, the antenna is disposed near the portion of the base casing where the upper casing is pivotally connected. When the portable electronic apparatus is in use, the upper casing has been unfolded relatively to the base casing. There is no much influence on the operation of the antenna by the upper casing, so the upper casing can be made of metal into a whole back plate. Furthermore, during the operation by a user on the portable electronic apparatus, the hands of the user will not cover the antenna so the influence by the user on the antenna is also limited. In short, the antenna can perform wireless communication function, even disposed beside the electronic device inside the host without excessive change in the disposition for the electronic devices inside the host, which solves the difficult choice in the prior art between the design for the metal casing and the function of the antenna.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of portable electronic apparatus of a preferred embodiment according to the present invention.

FIG. 2 is a top view of a part of the portable electronic apparatus in FIG. 1.

FIG. 3 is a top view of the base casing in FIG. 2.

FIG. 4 is a sectional view along the cutting line X-X of the base casing in FIG. 3.

FIG. 5 and FIG. 6 are two sectional views of the base casing according to different embodiments.

FIG. 7 is a sectional view along the cutting line Y-Y of the base casing in FIG. 3

FIG. 8 is a sectional view of the upper case of the display in FIG. 1.

FIG. 9 is a sectional view of the base casing of a portable electronic apparatus of another preferred embodiment according to the invention.

FIG. 10 and FIG. 11 are two sectional views of the base casing according to different embodiments.

### DETAILED DESCRIPTION

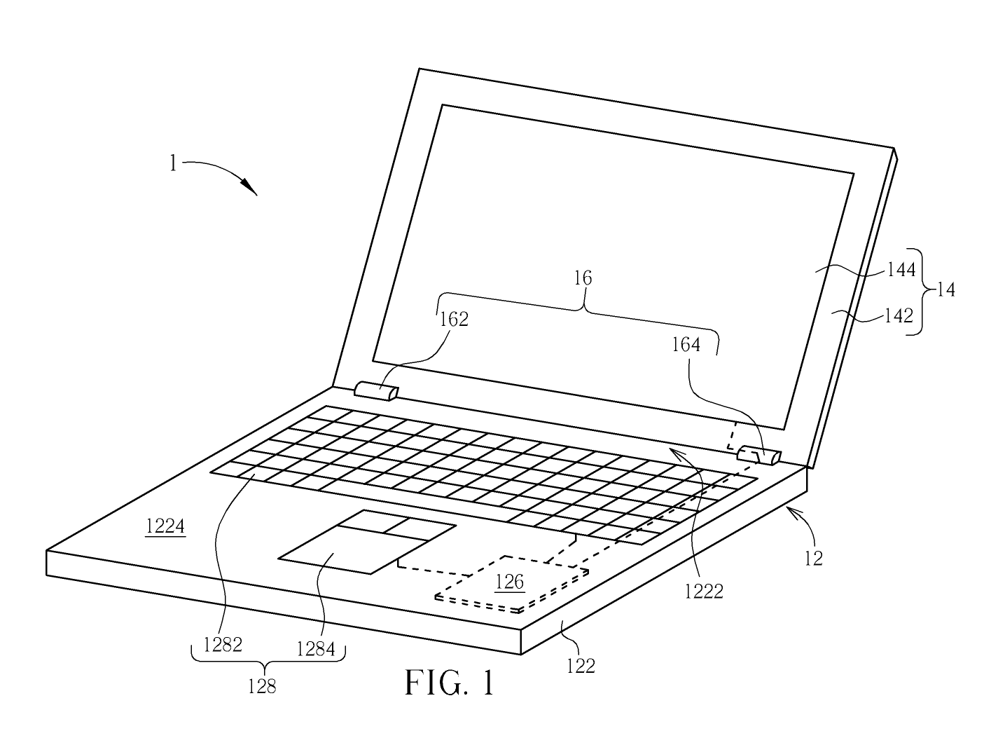

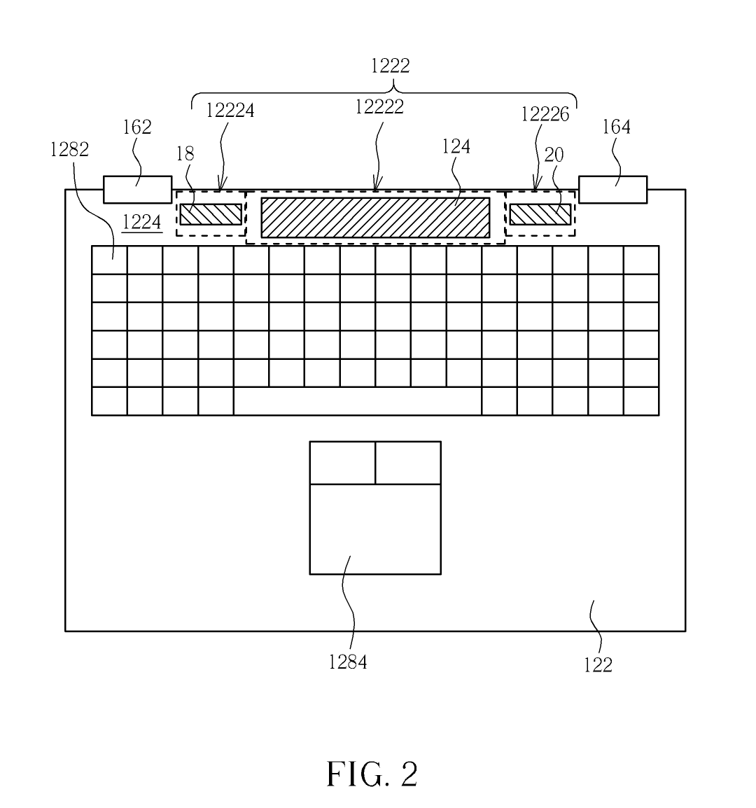

Please refer to FIG. 1 and FIG. 2. FIG. 1 is a schematic diagram of portable electronic apparatus 1 of a preferred embodiment according to the present invention. FIG. 2 is a top view of a part of the portable electronic apparatus 1 in FIG. 1. In this embodiment, the portable electronic apparatus 1 is a notebook, but the invention is not limited to this. The portable electronic apparatus 1 includes a host 12, a display 14 (not shown in FIG. 2), a pivotal connection device 16, a first antenna 18, and a second antenna 20. The host 12 includes a base casing 122 and an electronic device 124. The base casing 122 has a side portion 1222. The display 14 includes an upper casing 142, pivotally connected to the side portion 1222 by the pivotal connection device 16 so that the display 14 can rotate relatively to the host 12 to make the portable electronic apparatus 1 be in an unfolded state or a folded state. The base casing 122 thereon defines an antenna radiation reference surface 1224 as the reference for the radiation of the antennas 18 and 20. In the embodiment, the antenna radiation reference surface 1224 is the surface as well by which a user performs manual operation on the portable electronic apparatus 1. The antenna radiation reference surface 1224 can be taken as a plane logically. However, the invention is not limited to this. The side portion 1222 includes a first accommodating space 12222, a second accommodating space 12224, and a third accommodating space 12226. For simplifying the reading on the figures, the first antenna 18, the second antenna 20, the electronic device 124, the first accommodating space 12222, the second accommodating space 12224, and the third accommodating space 12226 are not shown and labeled in FIG. 1. In FIG. 2, the first accommodating space 12222, the second accommodating space 12224, and the third accommodating space 12226 are presented by frames in dashed lines for showing the substantial occupied space (which applies to the following figures as well); the first antenna 18, the second antenna 20, and the electronic device 124 are presented by hatched rectangles.

The first accommodating space 12222 is adjacent to the second accommodating space 12224. The third accommodating space 12226 is adjacent to the first accommodating space 12222 oppositely to the second accommodating space 12224. Projections of the first accommodating space 12222, the second accommodating space 12224, and the third accommodating space 12226 on the antenna radiation reference surface 1224 are non-overlapped. The electronic device 124 is disposed in the first accommodating space 12222. The first antenna 18 is disposed in the second accommodating space 12224. The second antenna 20 is disposed in the third accommodating space 12226. In the embodiment, the pivotal connection device 16 includes two hinges 162 and 164. The first accommodating space 12222, the second accommodating space 12224, and the third accommodating space 12226 between the two hinges 162 and 164. In practice, the quantity, type, and disposition of the hinges of the pivotal connection device according to the invention are not limited to the abovementioned. It is added that the host 12 includes a data-processing module 126 (shown in dashed lines in FIG. 1) and a manual input module 128, which are disposed in the base casing 122. The manual input module 128 includes a keyboard input interface 1282 and a touch pad 1284, which are exposed out of the antenna radiation reference surface 1224 for the manipulation by the user. The display 14 includes a displaying module 144 disposed in the upper casing 142. The data-processing module 126 is electrically connected to the manual input module 128 and the displaying module 144 (presented in dashed lines in FIG. 1), for processing the data inputted by the user by use of the keyboard input interface 1282 or the touch pad 1284 and displaying processing results by use of the displaying module 144.

According to the above description, the first antenna 18 and the second antenna 20 are disposed in the side portion 1222 pivotally connected to the upper casing 142. When the portable electronic apparatus 1 is in the unfolded state, the upper casing 142 does not influence the first antenna 18 and the second antenna 20 much; besides, when the portable electronic apparatus 1 is in use, the manipulation on the antenna radiation reference surface 1224 by the hands of the user will not cover the first antenna 18 and the second antenna 20. Furthermore, the electronic device 124 is disposed close to the first antenna 18 and the second antenna 20, but the electronic device 124 does not overlap the first antenna 18 and the second antenna 20 relatively to the antenna radiation reference surface 1224 and does not influence the radiating or receiving of signals of the first antenna 18 and the second antenna 20. Therefore, in the configuration of the portable electronic apparatus 1, the first antenna 18 and the second antenna 20 still can perform wireless communication function effectively.

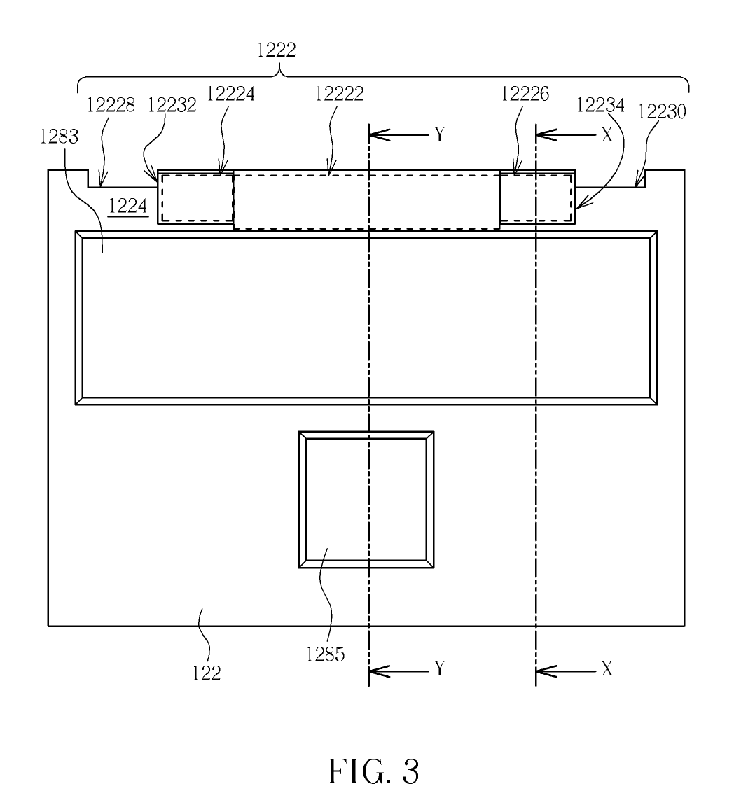

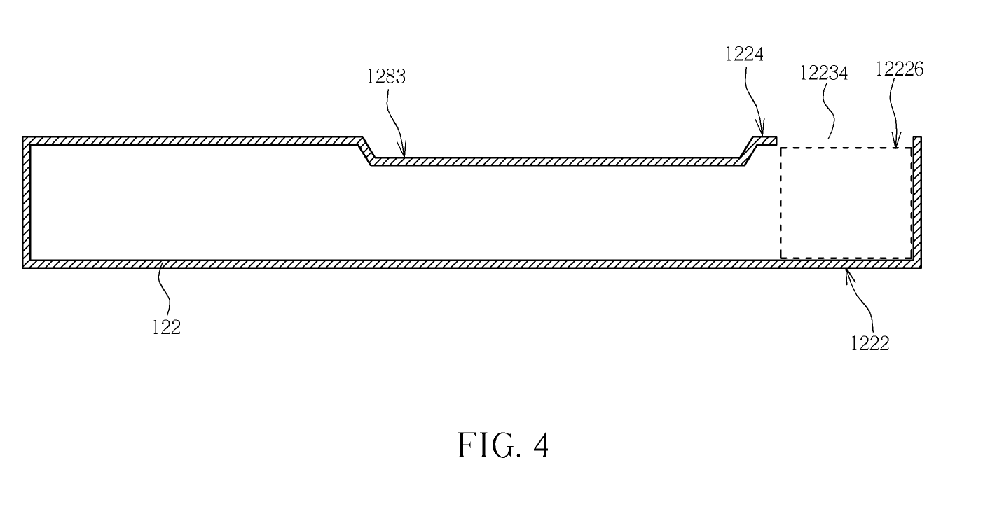

Please refer to FIGS. 2 through 4. FIG. 3 is a top view of the base casing 122 in FIG. 2. FIG. 4 is a sectional view along the cutting line X-X of the base casing 122 in FIG. 3; therein, for simplifying the reading, FIG. 4 only shows the profile of the base casing 122 at the cutting line X-X. The base casing 122 includes two sockets 1283 and 1285, for disposing the keyboard input interface 1282 and the touch pad 1284 respectively. The side portion 1222 of the base casing 122 includes two indentations 12228 and 12230 where the hinges 162 and 164 to be engaged to the side portion 1222. The side portion 1222 of the base casing 122 has two openings 12232 and 12234 on the antenna radiation reference surface 1224 correspondingly to the second accommodating space 12224 and the third accommodating space 12226 respectively. As shown in FIG. 4, the opening 12234 is formed only on the antenna radiation reference surface 1224. The second antenna 20 disposed in the third accommodating space 12226 can perform wireless communication through the opening 12234 toward the antenna radiation reference surface 1224.

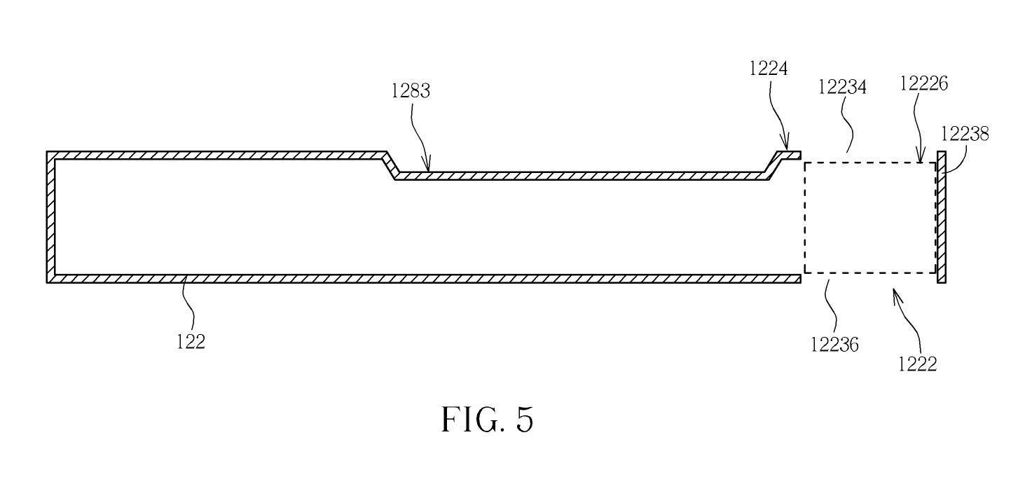

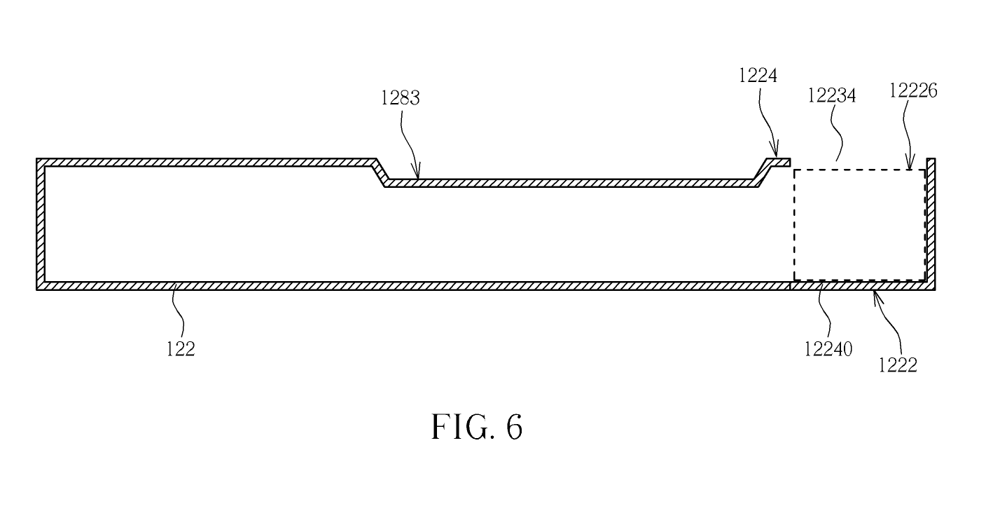

Please refer to FIG. 5. FIG. 5 is a sectional view of the base casing 122 according to another embodiment. By a different antenna design, the side portion 1222 of the base casing 122 can be formed with another opening 12236 opposite to the opening 12234, so that the base casing 122 forms a through passage along the projection direction of the second antenna 20 to the antenna radiation reference surface 1224. In the structure shown in FIG. 4 or FIG. 5, even if the base casing 122 is made of metal, because of no metal shielding in the radiation direction of the second antenna 20, the second antenna 20 still can perform wireless communication effectively. It is added that the base casing 122 in FIG. 4 and FIG. 5 is shown in one piece for ease of explanation; however the invention is not limited to this. In practice, the base casing 122 can be formed by combining a plurality of metal parts, for example by connecting a top metal part and a bottom metal part; other applicable embodiments are not repeatedly explained herein. Furthermore, in FIG. 5, the sidewall 12238 can be connected to any other portions of the base casing 122 along the direction perpendicular to the sheet of FIG. 5 in practice, not hung in the air. In a practical structure design, the sidewall 12238 can be removed together with the formation of the openings 12234 and 12236, or a casing structure 12240 made of nonmetal material is disposed there as shown in FIG. 6; therein, the casing structure 12240 still has the opening 12236, but the invention is not limited to this. In addition, though the above description is based on the embodiments of the second antenna 20, it is also applied to the structure of the second accommodating space 12224 where the first antenna 18 is disposed, which is not described more. Besides, in practice, the openings 12232 and 12234 can be covered with a casing made of nonmetal material for appearance consistence; however, the invention is not limited to this.

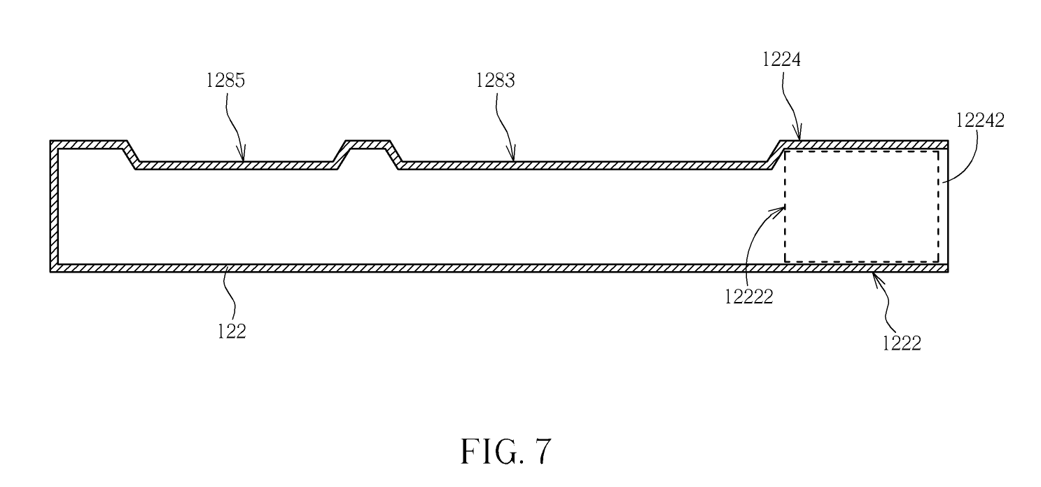

Please refer to FIG. 2, FIG. 3, and FIG. 7. FIG. 7 is a sectional view along the cutting line Y-Y of the base casing 122 in FIG. 3; therein, for simplifying the reading, FIG. 7 only shows the profile of the base casing 122 at the cutting line Y-Y. In the embodiment, the side portion 1222 of the base casing 122 has an opening 12242, which is conducive to disposing a removable electronic device and an electrical connector for connecting the removable electronic device in the first accommodating space 12222, for example a memory card and an electrical connector therefor. Besides, the structure design is also conducive to disposing electrical connectors in the first accommodating space 12222, for example communication ports, power connector and so on, for connecting external devices (such as printer, external storage media, expansion docking station). In practice, the first accommodating space 12222 can accommodate any other electronic device in conformity with the structure of the side portion 1222 relative to the first accommodating space 12222. In principle, just if the structure is allowable, the first accommodating space 12222 can accommodate various electronic devices, for example battery, hard disk, memory card and so on, not limited to the above examples.

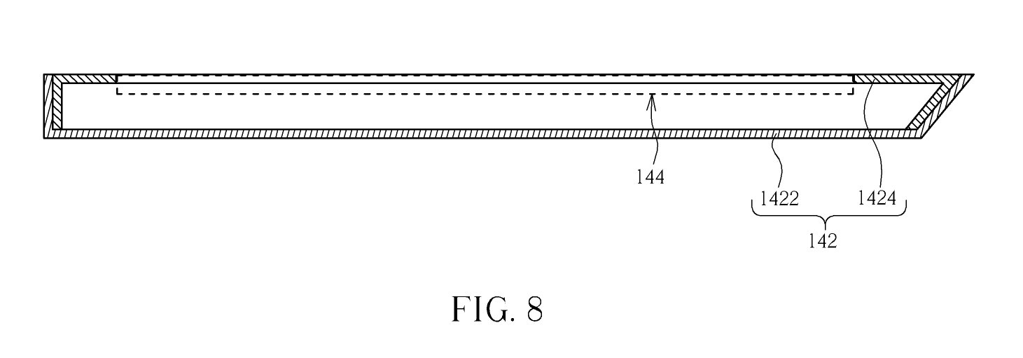

Please refer to FIG. 1 and FIG. 8. FIG. 8 is a sectional view of the upper case 142 of the display 14 in FIG. 1. The upper casing 142 mainly consists of a metal back plate 1422 and a frame 1424 engaged to the metal back plate 1422. The displaying module 144 is disposed in the upper casing 142 and provides displaying function through the window formed by the frame 1424. In the embodiment, the metal back plate 1422 covers the whole outward appearance of the upper casing 142, so the appearance of the portable electronic apparatus 1 meets the design requirement of the metal textural feeling and the strength of the whole metal back plate 1422 is preserved as well, which avoids the difficult choice in the prior art between the design for the metal casing and the function of the antenna. In practice, the upper casing 142 of the portable electronic apparatus 1 can mainly consist of a nonmetal back plate or more parts; the invention is not limited to this. It is added that the above embodiments are based on the notebook, but the invention is not limited to this. Any other foldable portable electronic apparatus is also applicable based on the invention.

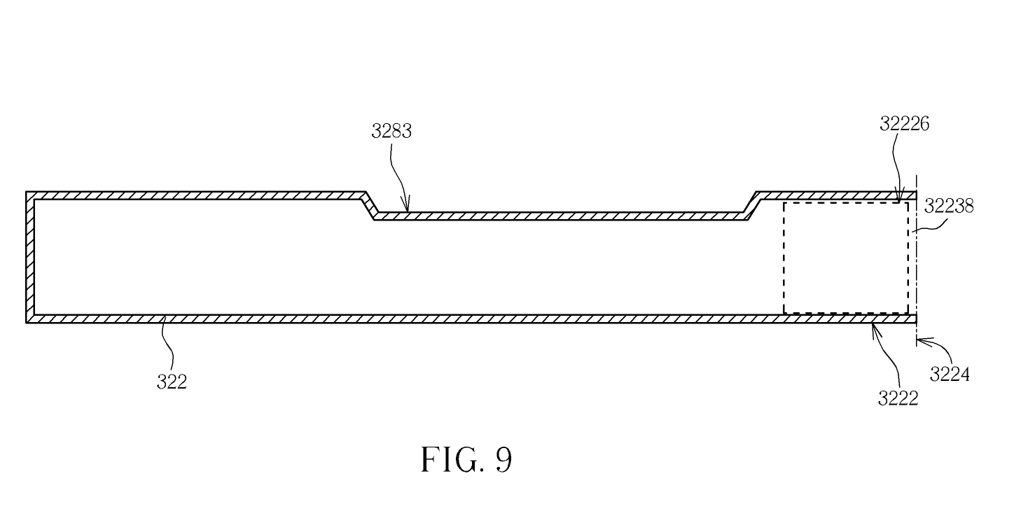

In the above embodiments, the antenna radiation reference surface 1224 is defined in the same plane direction as the keyboard of the portable electronic apparatus 1; however, the invention is not limited to this. Please refer to FIG. 9. FIG. 9 is a sectional view of the base casing 322 of a portable electronic apparatus of another preferred embodiment according to the invention. The structure of the portable electronic apparatus in this embodiment is substantially the same as the structure of the portable electronic apparatus 1 mentioned above. Hence, the following description focuses mainly on differences; therein, for the cutting position for the base casing 322 in FIG. 9, please refer to the position of the cutting line X-X in FIG. 3. As shown in FIG. 9, the socket 3283 of the base casing 322 is used for accommodating a keyboard. The side portion 3222 of the base casing 322 forms an opening 32238 at its edge; the position of the opening 32238 is substantially the same as that of the sidewall 12238. Therefore, the antenna radiation reference surface 3224 in the embodiment is at the edge of the side portion 3222. The antenna radiation reference surface 3224 is substantially perpendicular to the manipulation reference surface where the user manipulates the keyboard. Similarly, the antenna disposed in the third accommodating space 32226 can perform wireless communication through the opening 32238 toward the antenna radiation reference surface 3224. Furthermore, related descriptions of the first accommodating space, the second accommodating space, and other components are similar to those of components with same names of the portable electronic apparatus 1 and are no longer repeated.

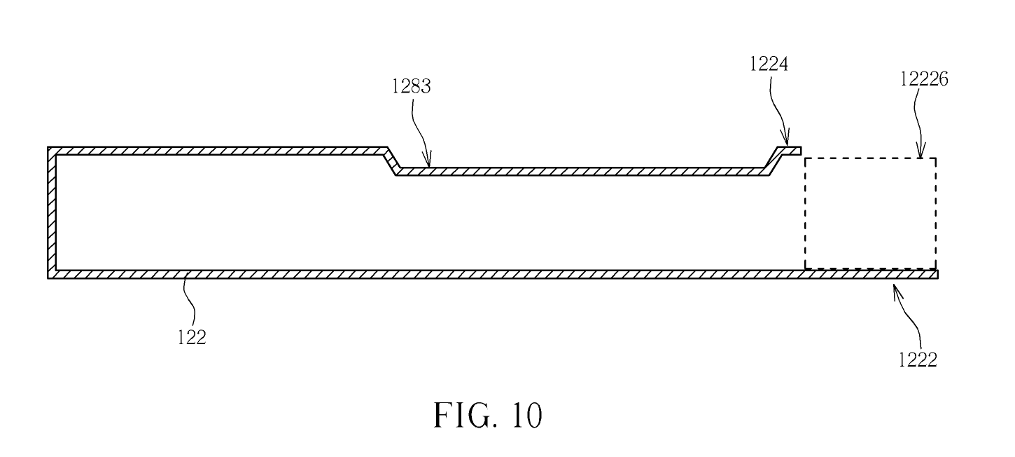

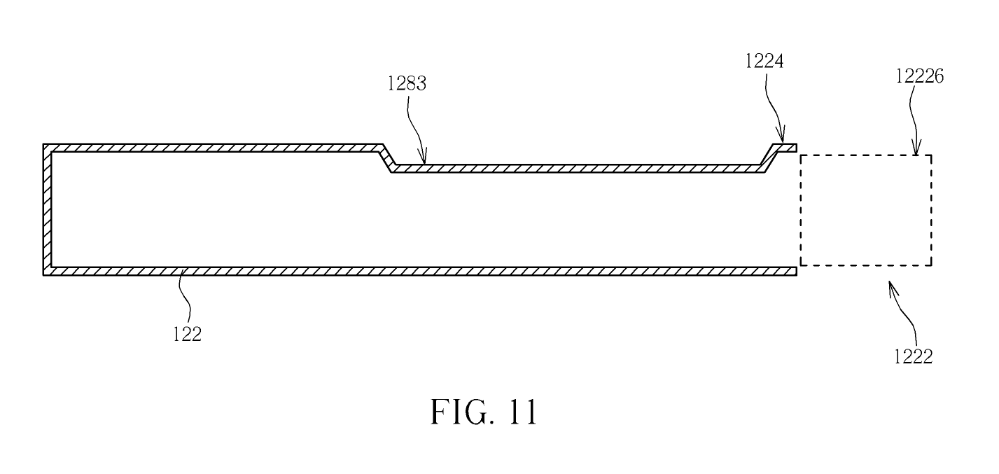

It is added that the above embodiments are explained according to the different positions of the antenna radiation reference surface; however, in practice, there could be an embodiment of two antenna radiation reference surfaces. For example, as shown in FIG. 10, the base casing 122 has only a bottom plate at the third accommodating space 12226 in this embodiment. For another example, as shown in FIG. 11, the base casing 122 is hollowed out at the third accommodating space 12226 in this embodiment; in this case, the antenna disposed in the third accommodating space 12226 has two radiation surfaces in two different directions for design. In addition, the opening of the base casing 122 in FIG. 9 and FIG. 10 may be engaged with a casing structure made of nonmetal material for protecting the antenna disposed in the third accommodating space 12226. For other descriptions of the embodiments in FIG. 9 and FIG. 10, please refer to the related descriptions in the other embodiments; they are no longer repeated.

As discussed above, in the portable electronic apparatus according to the invention, the antenna thereof is disposed near the portion of the base casing where the upper casing is pivotally connected, so even if the upper casing is made of metal, the antenna can operate normally when the portable electronic apparatus is in use. Furthermore, because the antenna can be disposed not on the upper casing, the back plate of the upper casing can be made in one piece and no broken hole is needed for the antenna, so that the appearance design of the upper casing becomes flexible. In addition, in the portable electronic apparatus according to the invention, the accommodating space for accommodating the antenna and the accommodating space for accommodating the electronic device are non-overlapped, so the antenna can be disposed beside the electronic device to still perform wireless communication function. Furthermore, the physical size of a general antenna is not large. Based on the spirit of the invention, the antenna can be easily integrated into the host configuration of a present notebook. Therefore, the invention can take both the appearance design of the upper casing and the function of the antenna into account without excessive loading in design modification.

Those skilled in the art will readily observe that numerous modifications and alterations of the device and method may be made while retaining the teachings of the invention.

What is claimed is:

1. A portable electronic apparatus, comprising:
a host, comprising a base casing and an electronic device, the base casing having a side portion, the base casing thereon defining an antenna radiation reference surface, the side portion having a first accommodating space and a second accommodating space, the first accommodating space being adjacent to the second accommodating space, projections of the first accommodating space and the second accommodating space on the antenna radiation reference surface being non-overlapped, the electronic device being disposed in the first accommodating space;
a pivotal connection device;
a display, comprising an upper casing, the upper casing being pivotally connected to the side portion by the pivotal connection device; and
a first antenna, disposed in the second accommodating space.

2. The portable electronic apparatus of claim 1, wherein the electronic device is a battery, an electrical connector, or a removable electronic device.

3. The portable electronic apparatus of claim 1, further comprising a second antenna, wherein the side portion has a third accommodating space, adjacent to the first accommodating space oppositely to the second accommodating space, and the second antenna is disposed in the third accommodating space.

4. The portable electronic apparatus of claim 1, wherein the upper casing comprises a metal back plate.

5. The portable electronic apparatus of claim 1, wherein the pivotal connection device comprises two hinges, and the first accommodating space and the second accommodating space are between the two hinges.

6. The portable electronic apparatus of claim 1, wherein the side portion has an opening on the antenna radiation reference surface correspondingly to the second accommodating space.

7. The portable electronic apparatus of claim 6, wherein the base casing is made of metal.

8. The portable electronic apparatus of claim 1, wherein the host comprises a data-processing module and a manual input module, disposed in the base casing, the manual input module comprises a keyboard input interface, exposed out of the antenna radiation reference surface, and the display comprises a displaying module, disposed in the upper casing.
